(19) United States
(12) Patent Application Publication
(10) Pub. No.: US 2024/0250324 A1
(43) Pub. Date: Jul. 25, 2024

(54) BATTERY TEMPERATURE SENSING USING COIL

(71) Applicant: Cirrus Logic International Semiconductor Ltd., Edinburgh (GB)

(72) Inventor: Matthew BEARDSWORTH, Austin, TX (US)

(73) Assignee: Cirrus Logic International Semiconductor Ltd., Edinburgh (GB)

(21) Appl. No.: 18/313,821

(22) Filed: May 8, 2023

Related U.S. Application Data
(60) Provisional application No. 63/440,936, filed on Jan. 25, 2023.

(51) Int. Cl. H01M 10/48; G01K 7/16; G01R 31/36; G01R 31/367; H01M 10/6571; H02J 50/10; H04B 5/00

(52) U.S. Cl. CPC H01M 10/486; G01K 7/16; G01R 31/3648; G01R 31/367; H01M 10/6571; H02J 50/10; H04B 5/0037

(57) ABSTRACT

A system and method may include a coil and a coil resistance and temperature reporting system electrically coupled to the coil and configured to monitor a direct current resistance of the coil and estimate a temperature of the coil based on the direct current resistance.

### RELATED APPLICATION

The present disclosure claims priority to U.S. Provisional Patent Application Ser. No. 63/440,936, filed Jan. 25, 2023, which is incorporated by reference herein in its entirety.

### FIELD OF DISCLOSURE

The present disclosure relates in general to circuits for electronic devices, including without limitation personal audio devices such as mobile telephones, tablet and laptop computers, portable media players, and portable gaming devices, and more specifically, to sensing a temperature associated with a battery using a coil located in proximity to the battery.

### BACKGROUND

Rechargeable batteries or cells are used to power a wide range of electronic devices such as, for example, mobile telephones, tablet and laptop computers, portable media players, portable gaming devices and the like. The charging performance of such batteries or cells, in terms of charging speed, efficiency, charging capacity, battery life following charging or other parameters, may vary according to at least the temperature of the battery or cell and/or the temperature gradient across the battery or cell. For some battery or cell chemistries, the charging performance may be improved or optimized if the battery or cell is maintained at a predetermined temperature or within a predetermined temperature range during charging.

Traditionally, most batteries implement a negative temperature coefficient (NTC) thermistor or other localized temperature sensor adjacent to the battery cell to estimate the cell temperature. These methods may only provide rough estimation of the average battery temperature because the battery is large and the sensor is only located in one region of the battery, usually near the battery cell tabs (where protection circuits and fuel gauge devices are attached to the cell) for manufacturing and assembly ease. While these tabs can be prone to hot spotting due to the high current density from aggregate flow of current in and out of the cell layers, this localized temperature sensor does not measure temperature conditions across the entire cell.

### SUMMARY

In accordance with the teachings of the present disclosure, one or more disadvantages and problems associated with existing approaches to sensing battery temperature may be reduced or eliminated.

In accordance with embodiments of the present disclosure, a system may include a coil and a coil resistance and temperature reporting system electrically coupled to the coil and configured to monitor a direct current resistance of the coil and estimate a temperature of the coil based on the direct current resistance.

In accordance with these and other embodiments of the present disclosure, a method may include monitoring a direct current resistance of a coil and estimating a temperature of the coil based on the direct current resistance.

In accordance with these and other embodiments of the present disclosure, a system may include a battery, at least one component electrically coupled to and powered from the battery, a coil located proximate to the battery such that a temperature of the coil is indicative of a temperature of the battery, a coil resistance and battery temperature reporting system electrically coupled to the coil and configured to monitor a direct current resistance of the coil and estimate a temperature of the coil based on the direct current resistance, and a power management system communicatively coupled to the coil resistance and battery temperature reporting system, the battery, and the at least one component and configured to control power delivered and consumed by the battery and the at least one component based on the temperature of the coil.

In accordance with these and other embodiments of the present disclosure, a method may include monitoring a direct current resistance of a coil located proximate to a battery such that a temperature of the coil is indicative of a temperature of the battery, estimating a temperature of the coil based on the direct current resistance, and controlling power delivered and consumed by the battery and at least one component electrically coupled to and powered from the battery based on the temperature of the coil.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates an example block diagram of selected components of a battery-powered electronic device, in accordance with embodiments of the present disclosure;

FIG. 2 illustrates an example block diagram of selected components of a coil resistance and battery temperature reporting subsystem, in accordance with embodiments of the present disclosure;

FIG. 3 illustrates a side cross-sectional view of selected components of a battery-powered electronic device, in accordance with embodiments of the present disclosure;

FIG. 4A illustrates an example equivalent circuit thermal model of a coil and battery system when a coil is a source of heat, in accordance with embodiments of the present disclosure;

FIG. 4B illustrates an example equivalent circuit thermal model of a coil and battery system when a battery is a source of heat, in accordance with embodiments of the present disclosure; and

FIG. 5 illustrates an example block diagram of selected components of the battery-powered electronic device depicted in FIG. 1, in accordance with embodiments of the present disclosure.

### DETAILED DESCRIPTION

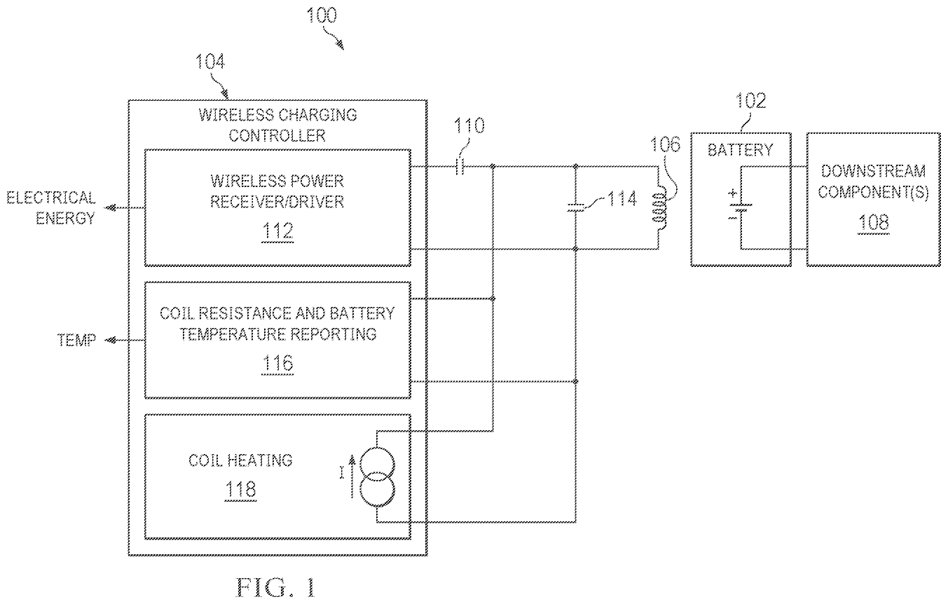

FIG. 1 illustrates an example block diagram of selected components of a battery-powered electronic device 100, in accordance with embodiments of the present disclosure. Electronic device 100 may be any suitable electronic device, including without limitation a mobile phone, smart phone, tablet, laptop/notebook computer, media player, handheld, smart watch, gaming controller, etc. As shown in FIG. 1, electronic device 100 may include a battery 102, one or more downstream components 108 which may be powered from battery 102, and a wireless charging subsystem comprising wireless controller 104 electrically coupled to a coil 106 located in proximity to battery 102 such that heat may readily transfer between battery 102 and coil 106 and vice versa. As shown in FIG. 1, a direct current (DC) blocking capacitor 110 may be coupled between coil 106 and a wireless power receiver/driver 112 of wireless charging controller 104, and a tank capacitor 114 may be coupled in parallel with coil 106.

Battery 102 may include any system, device, or apparatus configured to convert chemical energy stored within battery 102 to electrical energy. For example, in some embodiments, battery 102 may be integral to a portable electronic device, and battery 102 may be configured to deliver electrical energy to downstream component(s) 108 of electronic device 100. Further, battery 102 may also be configured to recharge, in which it may convert electrical energy received by battery 102 from wireless power receiver/driver 112 via coil 106 into chemical energy to be stored for later conversion back into electrical energy. As an example, in some embodiments, battery 102 may comprise a lithium-ion battery.

Coil 106 may comprise any suitable electrical conductor arranged in a coiled shape or geometry, so as to possess a significant electrical inductance.

Wireless power receiver/driver 112 may include any system, device, or apparatus configured to, when coil 106 is inductively coupled to a charging source, receive electrical energy from such charging source and control delivery of such energy to components of electronic device 100, including without limitation battery 102 and/or downstream component(s) 108. For example, in some embodiments, wireless power receiver/driver 112 may include an inductive buck converter comprising an inductor and one or more switches for performing buck-based functionality for wireless power receiver/driver 112. However, any suitable regulator may be used to implement wireless power receiver/driver 112, including without limitation a switched-capacitor regulator, a hybrid regulator, and a multi-level regulator.

Downstream component(s) 108 may include any suitable component that may be driven by battery 102, including without limitation a speaker, haptic transducer, other transducer, power system (e.g., voltage regulator, power converter, etc.), processor, audio coder/decoder, amplifier, display device, etc.

As shown in FIG. 1, wireless charging controller 104 may also include coil resistance and battery temperature reporting subsystem 116, which may include any suitable system, device, or apparatus configured to sense a resistance of coil 106 and from such resistance, estimate and report a temperature proximate to battery 102. Such temperature may be used by other components of electronic device 100 to control management of battery 102, including charging and discharging of battery 102 and temperature management of battery 102, as described in greater detail below.

Although FIG. 1 depicts coil resistance and battery temperature reporting subsystem 116 integral to wireless charging controller 104, in some embodiments, coil resistance and battery temperature reporting subsystem 116 may be external to/independent of wireless charging controller 104, particularly in embodiments in which wireless charging is not implemented within electronic device 100. However, in embodiments in which wireless charging is implemented within electronic device 100, placement of a coil 106 used for wireless charging proximate to battery 102 and use of coil resistance of coil 106 in measuring battery temperature may allow for efficient temperature measurement due to the large area of coil 106 relative to battery 102 and may allow for efficient temperature measurement without the need for much additional hardware, as coil 106 may be used not only for traditional wireless charging but further leveraged for temperature measurement.

As also shown in FIG. 1, wireless charging controller 104 may also include coil heating subsystem 118, which may include any suitable system, device, or apparatus configured to generate a current I for heating coil 106. In some embodiments, current I may comprise a direct current, in order to maximize desired heating of coil 106 in response to current I. Thus, in addition to or in lieu of being used to measure temperature, coil 106 may be used as a resistive heating element to heat battery 102. For example, if coil resistance and battery temperature reporting subsystem 116 and/or another temperature measurement subsystem of electronic device 100 determines that a temperature associated with battery 102 is below a threshold temperature, coil resistance and battery temperature reporting subsystem 116 may cause coil heating subsystem 118 to deliver electrical energy to coil 106. Flow of current through coil 106 may cause coil 106 to heat due to resistive losses, which in turn may heat battery 102 to above the threshold temperature. For example, if battery 102 is cooler than is optimal for charging, coil resistance and battery temperature reporting subsystem 116 may cause coil heating subsystem 118 to heat battery 102 to the desired level before battery 102 charging is initiated.

Coil heating subsystem 118 may drive electrical energy to coil 106 to heat battery 102 at any suitable time, including before or during a battery charging or discharging event. Heating of battery 102 may be performed simultaneously with temperature measurement using coil 106, as described above, or such heating may be time multiplexed with temperature measurement.

In some embodiments, such heating of battery 102 using coil 106 may be performed to regulate a temperature of battery 102 to a desired temperature in a feedback control loop. Although FIG. 1 shows coil heating subsystem 118 configured to deliver electrical energy to coil 106, electrical energy for heating coil 106 may be provided by received AC wireless charging energy from an externally-coupled charging coil, transmitted AC wireless charging energy delivered to an externally-coupled charging coil, electrical energy from a wired charger coupled to electronic device 100, and/or from battery 102 itself. When heating coil 106, coil 106 may be temporarily modified allowing a maximum amount of the coil energy to be converted to heat, including without limitation techniques such as shorting coil connections of coil 106 and using a region of coil 106 having a higher resistance.

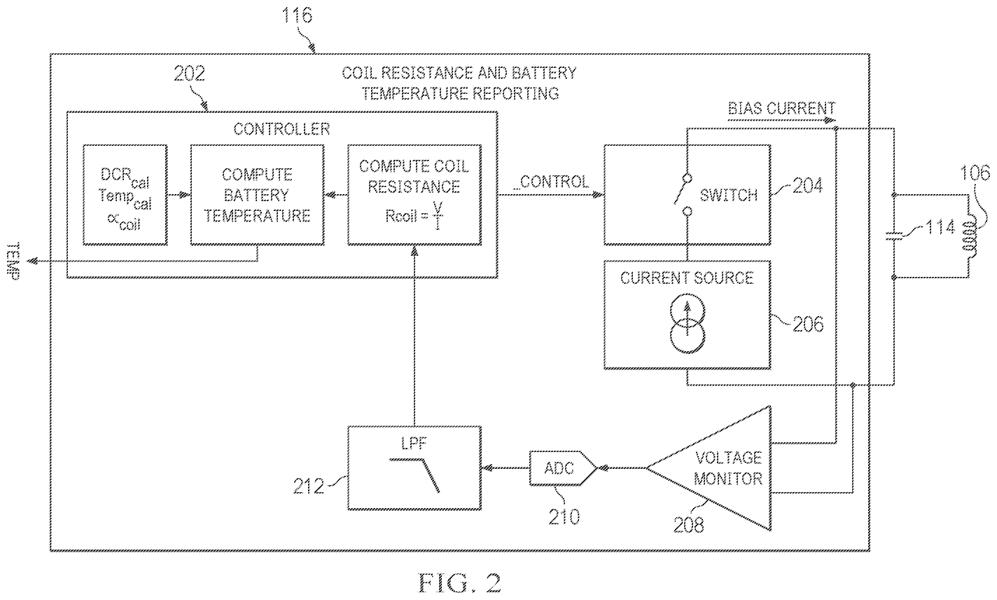

FIG. 2 illustrates an example block diagram of selected components of coil resistance and battery temperature reporting subsystem 116 electrically coupled to coil 106 and tank capacitor 114, in accordance with embodiments of the present disclosure. As shown in FIG. 2, coil resistance and battery temperature reporting subsystem 116 may include a controller 202, a switch 204, a current source 206, a voltage monitor 208, an analog-to-digital (ADC) controller 210, and a low-pass filter 212.

To enable temperature measurement using coil 106, controller 202 may generate a control signal to close switch 204 such that current source 206 drives a known bias current I to coil 106. Voltage monitor 208 may sense an analog voltage V across the terminals of coil 106, and ADC 210 may convert such analog voltage V into a digitally-equivalent signal. Low-pass filter 212 may perform low-pass filtering on the digitally-equivalent signal to filter out any noise associated with voltage monitoring.

Based on the bias current I and the measured voltage V (as filtered by low-pass filter 212), controller 202 may compute DC resistance R_{COIL} of coil 106 as R_{COIL}=V/I. Further, based on DC resistance R_{COIL} and initial coil parameters for coil 106, controller 202 may compute and report a temperature associated with battery 102. For example, in some embodiments, battery temperature Temp may be given by:

$$Temp = {Temp}_{c a l} + \frac{{R}_{COIL} - {R}_{c a l}}{{R}_{c a l} {∝}_{c a l}}$$

where R_{cal} is the recorded DC coil resistance at a known coil temperature Temp_{cal}, and ∝_{cal} is a conductive coefficient of coil 106. Such initial coil parameters R_{cal}, Temp_{cal}, and ∝_{cal} may be stored in a memory (e.g., read-only memory or random access memory) accessible to controller 102. Initial coil parameters may be determined in any suitable manner, including during a calibration step in which DC resistance of coil 106 is measured at a known temperature, or may be determined by coil design and manufacturing tolerances where R_{cal} and Temp_{cal} have been previously characterized and determined to be representative of a specific design of coil 106.

The bias current generated by current source 206 may be a direct current (DC) stimulus or an alternating current (AC) stimulus. In the case of an AC stimulus, such stimulus could be low enough in frequency such that the inductive reactance of coil 106 is small enough such that the measured resistance is effectively the DC resistance R_{COIL}. Such AC stimulus may be the transmitted AC wireless charging power signal generated by wireless charging controller 202 or another power inverter, the received AC wireless charging power signal as provided by a wireless charger external to electronic device 100, or any other suitable sinusoid, square wave, ramp, or other complex waveform.

In some instances, an AC coil stimulus could be used to extract an impedance of coil 106 in addition to or in lieu of DC resistance R_{COIL}. Accordingly, a temperature of battery 102 may be estimated based on monitored inductance in addition to or in lieu of monitored resistance. Although not depicted in the FIGURES, in some embodiments a phase detector circuit could be added to the sensing path, and both the real and imaginary parts of the impedance measurement could be calculated, allowing for independent measurement of both inductance and resistance of coil 106.

The battery temperature Temp estimated and reported by controller 202 may be used in isolation or may be used in conjunction with any other temperature information associated with battery 102 (e.g., information from a separate negative temperature coefficient temperature sensor) in order to control battery management. For example, the temperature measurement may be used: to modify device charging behavior (e.g., charge voltage, charge current, start or end of charging), to modify device discharging behavior (e.g., battery current limits to manage brownout/performance of system side loads), to modify battery state of charge and/or available capacity reported to a user and/or internal battery management systems, to shut down electronic device 100 during extreme temperature events, and/or as part of a feedback loop to control temperature of coil 106 by varying an amount of power delivered from or consumed by either battery 102 and/or power delivery systems of electronic device 100.

In implementation, coil resistance and battery temperature reporting subsystem 116 may be implemented as a standalone integrated circuit, or may comprise a subcircuit of an existing integrated circuit of electronic device 100. For example, as shown in FIG. 1, coil resistance and battery temperature reporting subsystem 116 may comprise a subcircuit of wireless charging controller 104, and in many instances, integration of coil resistance and battery temperature reporting subsystem 116 into wireless charging controller 104 may be the most economic design choice. Any battery-powered device with wireless charging may already include a wireless charging controller, and such wireless charging controller may have electrical connections to a coil for wireless charging, thus minimizing routing complexity and number of conductors to couple to coil resistance and battery temperature reporting subsystem 116.

When implemented using a coil also used for wireless charging, coil resistance and battery temperature reporting subsystem 116 may monitor DC resistance R_{COIL} of coil 106 either by time multiplexing wireless charging transmission with periodic resistance checks (e.g., by appropriately controlling switch 204) or by superimposing resistance checks during simultaneous wireless charging. For example, in some embodiments, the resistance measurement path may include a filter network (e.g., low-pass, bandpass, etc.) that may filter out artifacts associated with wireless charging from the resistance measurement and/or filter out frequency content in the coil voltage associated with transmission by coil 106. Such filtering may also remove any additional erroneous external noise sources that coupled into coil 106 as a receiver.

Coil resistance and battery temperature reporting subsystem 116 may trigger measurements of DC resistance R_{COIL} of coil 106 and battery temperature Temp periodically at a desired rate, continuously, in response to a device charging state (e.g., charger of battery 102 plugged in, battery 102 reaches specified state of charge, etc.), and/or in response to a change in load characteristics of battery 102.

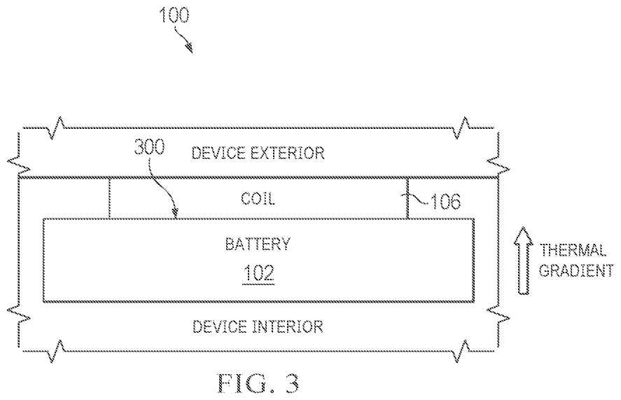

With battery 102 located sufficiently proximate to coil 106, windings of coil 106 may reach thermal equilibrium with battery 102. Thus, using known conductivity coefficient ∝_{cal} of coil 106, DC resistance R_{COIL} of coil 106 may thus track a temperature of battery 102. While most existing devices are designed with limited consideration of the thermal interface between battery 102 and coil 106 used for wireless charging, thermal coupling between battery 102 and coil 106 may be maximized by use of a thermal compound 300 interfaced between battery 102 and coil 106, as depicted in FIG. 3. FIG. 3 illustrates a side cross-sectional view of selected components of electronic device 100, in accordance with embodiments of the present disclosure. As shown in FIG. 3, when heat is generated by battery 102, a thermal gradient may exist from battery 102 to coil 106 across thermal compound 300.

Thermal modeling of thermal time constants, thermal capacity, and thermal resistance of the thermal system of battery 102 and coil 106 may be used to further improve accuracy of temperature measurement of battery 102. While it may be desirable to minimize thermal gradients between battery 102 and coil 106, a thermal model may enable improved measurement accuracy under a wide range of scenarios especially when electronic device 100 is exposed to hot or cold temperatures. For example, a thermal model may be useful for accounting for:
Large swings in an ambient temperature external to electronic device 100 which can impose gradients across an exterior chassis of electronic device 100 and thus across battery 102 and coil 106;
Large swings in internal device temperatures (e.g., from processors, graphics processors, power supply circuits, etc.) that may impose gradients across battery 102 and coil 106; and
Steady state offsets in temperature between battery 102 and coil 106;
Steady state offsets in gradients between the surface of battery 102 (e.g., where coil 106 may be located) to the center of battery 102 and across the opposite end of battery 102.

Such a battery model may be stored in memory of an electronic device and may be used to modify reported battery temperature Temp. Various inputs to such model may include, without limitation, battery power dissipation information, battery voltage information, battery current information, coil power dissipation information, coil voltage information, coil current information, coil temperature information, battery temperature information, thermal resistance information associated with mechanical elements, and/or thermal capacity information. Modeled parameters of a battery model may be modified or changed in real time based on device state, such as whether a device is drawing power from battery 102, whether battery 102 is being charged via a wired connection, and/or whether battery 102 is being charged wirelessly.

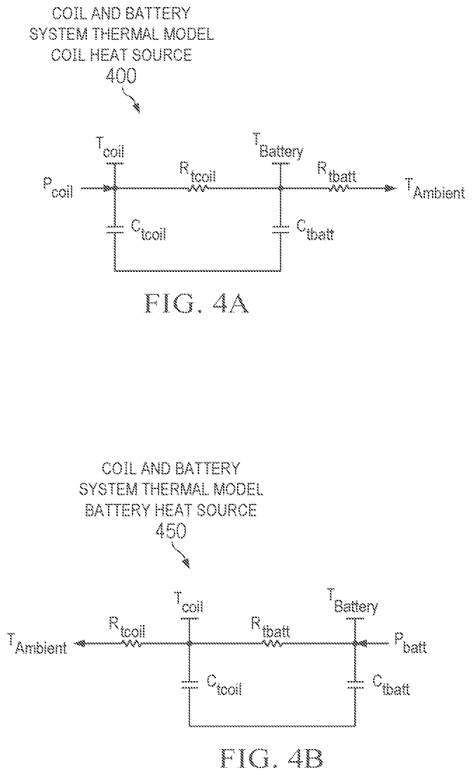

FIG. 4A illustrates an example equivalent circuit thermal model 400 of a coil and battery system when a coil (e.g., coil 106) is a source of heat, in accordance with embodiments of the present disclosure. FIG. 4B illustrates an example equivalent circuit thermal model 450 of a coil and battery system when a battery (e.g., battery 102) is a source of heat, in accordance with embodiments of the present disclosure. However, modeling of a coil and battery system is not limited to the example equivalent circuit thermal models shown in FIGS. 4A and 4B, and in some embodiments, an equivalent circuit thermal model may be more complex than that depicted.

Heating of coil 106 (e.g., using coil heating subsystem 118 as described above) may also be used to extract thermal model parameters, including thermal time constants, thermal capacity, and thermal resistance for a coil and battery model, such as those models depicted in FIGS. 4A and 4B. Power dissipated into coil 106 may be determined based on a current or voltage (known or measured) driven into coil 106 and measuring DC coil resistance R_{COIL}, as described above. By measuring DC coil resistance R_{COIL}, in real time, the heating power for coil 106 may always be known even when DC coil resistance R_{COIL} increases due to the coil heating itself.

By pulsing the heating power for coil 106 at a periodic on/off rate, a thermal gradient between coil 106 and battery 102 may ensure a temperature gradient between coil 106 and battery 102 during both the on events and the off events, wherein battery 102 may reach thermal equilibrium with coil 106 during the off events. Because battery 102 may have a larger thermal mass than coil 106, coil 106 may tend to heat quicker than battery 102 during the on events, and during the off events, coil 106 may quickly cool to the temperature of battery 102. Accordingly, coil resistance and battery temperature reporting subsystem 116 may monitor coil temperature during the pulsed heating sequence using temperature measurement techniques described herein. Further, the monitored coil temperature data in conjunction with the coil power may be analyzed to extract a thermal model of heat transfer from coil 106 to battery 102 (e.g., using model 400 of FIG. 4A).

In some embodiments, geometry of coil 106 may be designed in order to maximize accuracy and signal-to-noise ratio of temperature measurement, for instance by minimizing the effect of unwanted (e.g., non-battery) device temperature changes on coil resistance and maximizing the effect of battery temperature changes to coil resistance. Accordingly, coil 106 may be designed to compensate for a lack of overlap between battery 102 and coil 106, to compensate for temperature changes seen from components of electronic device 100 other than battery 102, to allow for measuring battery temperature at different regions of battery 102 (e.g., multi-zone monitoring), to equalize battery heating across the entire battery 102, and/or to maximize battery heating by coil 106 when desired. Features of coil 106 that may be designed to accomplish such objective may include, without limitation, overall size and shape, use of multiple coils (e.g., where resistance measurements and/or heating may be independent across the multiple coils), use of tapped coils (e.g., where resistance measurements and/or heating may be independent across multiple regions of a single coil), use of coils with differing conductor thickness within a single continuous coil, use of claims with differing conductor width within a single continuous coil (e.g., placing more or less coil conductor surface area in desirable regions), coils with differing conductor spacing within a single continuous coil, and/or coils with materials of non-uniform resistivity within a single continuous coil.

In some embodiments, coil modifications may be dynamic in nature, wherein the coil configurations may be modified electrically using appropriate switches while electronic device 100 is in operation and with such modifications dependent on device state (e.g., wireless charging, wired charging, battery discharging, battery heating, etc.).

Further, while the foregoing contemplates the integration of battery temperature sensing with the same coil used to implement wireless charging, in some embodiments, a secondary coil located proximate to battery 102 may be used exclusively for battery temperature sensing and/or battery heating, thus separating functions between wireless charging of battery 102 and temperature sensing of battery 102 using two independent coil structures.

In these and other embodiments, a differential temperature sensing system may be implemented by using two coils, wherein one coil is placed in proximity to battery 102 while other coil may be used to monitor an internal temperature of electronic device 100 other than that of battery 102. Similarly, in some embodiments, a differential temperature sensing system may be implemented using coil 106 to measure temperature of battery 102 and another temperature sensor (e.g., negative temperature coefficient sensor, thermistor, etc.) configured to measure another temperature other than that of battery 102. Such other sensor may be used to monitor an internal ambient temperature of electronic device 100, nearby or thermally-coupled components or circuits that may affect heating or cooling of battery 102, and/or external ambient temperatures. The difference between the temperature of coil 106 and such other monitored temperature may indicate a polarity and magnitude of a temperature gradient between battery 102 and such other monitored device. Thus, use of such differential temperature sensing may further enhance battery thermal modeling and battery temperature accuracy.

While the foregoing contemplates use of a coil 106 used for wireless charging of an electronic device 100 in order to measure temperature of and/or provide heat to battery 102, it is understood that in some embodiments, coil 106 used to measure temperature of and/or provide heat to battery 102 may be implemented with a coil not otherwise used for wireless charging, such as a Near Field Communication (NFC) coil used for communication or a coil specifically dedicated to measure temperature of and/or provide heat to battery 102.

Moreover, in addition to using a coil to measure temperature of and/or provide heat to battery 102, the techniques described herein may also be used to extract temperature information and/or provide heating of any other component that possesses a coil or winding, including without limitation inductors, transformers, magnetic components, etc.

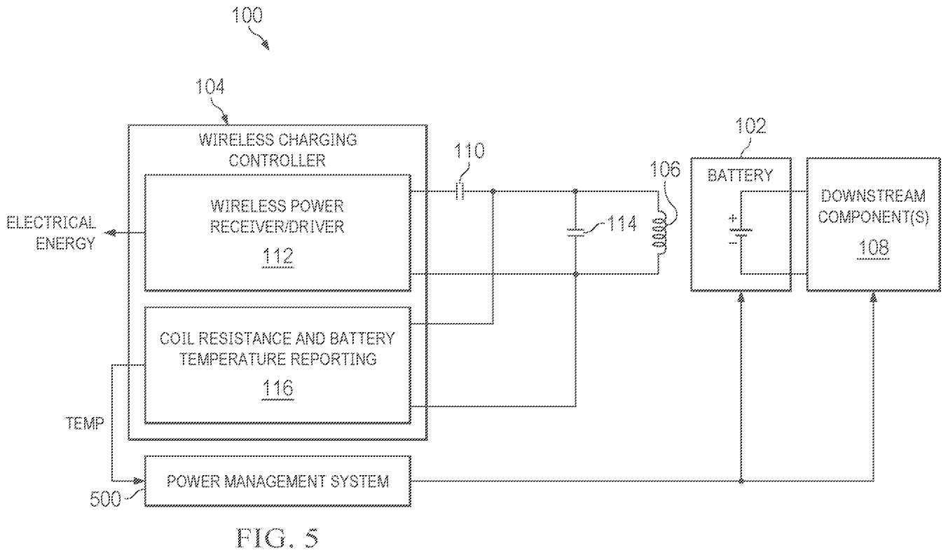

As briefly mentioned above, the temperature measurement techniques described herein may be used as part of a feedback loop to control temperature of coil 106 by varying an amount of power delivered from or consumed by either battery 102 and/or power delivery systems of electronic device 100. FIG. 5 illustrates an example block diagram of selected components of battery-powered electronic device 100, with additional detail including a power management system 500, in accordance with embodiments of the present disclosure. As shown in FIG. 5, power management system 500 may receive the estimated temperature Temp reported by coil resistance and battery temperature reporting subsystem 116 and based on such temperature, may control power delivery/consumption of battery 102 and/or one or more of downstream component(s) 108, in order to regulate estimated temperature Temp in a feedback manner.

Although the present disclosure and certain representative advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. For example, where general purpose processors are described as implementing certain processing steps, the general purpose processor may be a digital signal processor (DSP), a graphics processing unit (GPU), a central processing unit (CPU), or other configurable logic circuitry. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding embodiments described herein may be utilized. Accordingly, the appended claims are intended to include within their scope such processes, machines, manufacture, compositions of matter, means, methods, or steps.

The circuitry described above with reference to the accompanying drawings may be incorporated in a host device, preferably a battery-powered host device, such as a laptop, notebook, netbook or tablet computer, a gaming device such as a games console or a controller for a games console, a virtual reality (VR) or augmented reality (AR) device, a mobile telephone, a portable audio player or some other portable device, a power tool or other handheld electronic device, a wearable device such as a wearable health monitor, or may be incorporated in an accessory device for use with a laptop, notebook, netbook or tablet computer, a gaming device, a VR or AR device, a mobile telephone, a portable audio player or other portable device. The described circuitry may be incorporated into a vehicle or other automotive product.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. A system comprising:
a coil; and
a coil resistance and temperature reporting system electrically coupled to the coil and configured to:
monitor a direct current resistance of the coil; and
estimate a temperature of the coil based on the direct current resistance.

2. The system of claim 1, wherein monitoring the direct current resistance comprises:
measuring an electrical signal associated with the coil responsive to an electrical bias driven on the coil; and
estimating the direct current resistance based on the electrical bias and the electrical signal.

3. The system of claim 2, wherein the electrical bias comprises an electrical current and the electrical signal comprises an electrical voltage.

4. The system of claim 1, further comprising a battery located proximate to the coil such that the temperature of the coil is indicative of a temperature of the battery.

5. The system of claim 4, wherein the battery is thermally coupled to the coil via a thermal compound.

6. The system of claim 1, wherein the coil is integral to a wireless charging subsystem of an electronic device comprising the system.

7. The system of claim 1, wherein the coil is a Near Field Communication (NFC) coil used for communication of an electronic device comprising the system.

8. The system of claim 1, further comprising a battery modeling subsystem configured to calculate parameters of an equivalent circuit thermal model associated with the coil based on the temperature.

9. The system of claim 1, wherein the coil resistance and temperature reporting system is further configured to drive electrical current to the coil in order to heat the coil.

10. The system of claim 1, wherein the coil resistance and temperature reporting system is further configured to drive electrical current to the coil in order to heat the coil in response to the temperature falling below a threshold temperature.

11. The system of claim 1, wherein estimating the temperature of the coil comprises estimating the temperature based on the direct current resistance and initial thermal parameters associated with the coil.

12. The system of claim 11, wherein the initial thermal parameters comprise a value of the direct coil resistance recorded at a known temperature of the coil and a conductive coefficient of the coil.

13. A method comprising:
monitoring a direct current resistance of a coil; and
estimating a temperature of the coil based on the direct current resistance.

14. The method of claim 13, wherein monitoring the direct current resistance comprises:
measuring an electrical signal associated with the coil responsive to an electrical bias driven on the coil; and
estimating the direct current resistance based on the electrical bias and the electrical signal.

15. The method of claim 14, wherein the electrical bias comprises an electrical current and the electrical signal comprises an electrical voltage.

16. The method of claim 13, further comprising locating the coil proximate to a battery such that the temperature of the coil is indicative of a temperature of the battery.

17. The method of claim 16, further comprising thermally coupling the battery to the coil via a thermal compound.

18. The method of claim 13, wherein the coil is integral to a wireless charging subsystem of an electronic device.

19. The method of claim 13, wherein the coil is a Near Field Communication (NFC) coil used for communication of an electronic device.

20. The method of claim 13, further comprising calculating parameters of an equivalent circuit thermal model associated with the coil based on the temperature.

21. The method of claim 13, further comprising driving electrical current to the coil in order to heat the coil.

22. The method of claim 13, further comprising driving electrical current to the coil in order to heat the coil in response to the temperature falling below a threshold temperature.

23. The method of claim 13, wherein estimating the temperature of the coil comprises estimating the temperature based on the direct current resistance and initial thermal parameters associated with the coil.

24. The method of claim 23, wherein the initial thermal parameters comprise a value of the direct coil resistance recorded at a known temperature of the coil and a conductive coefficient of the coil.

25. A system comprising:
a coil;
a wireless charging circuit electrically coupled to the coil and configured to receive electrical energy from a source of electrical energy and control delivery of the electrical energy to one or more components of an electronic device via the coil, wherein the one or more components are wirelessly inductively coupled to the coil; and
a coil heating subsystem configured to drive electrical current, other than electrical current provided by the wireless charging circuit, to the coil in order to heat the coil.

26. The system of claim 25, wherein the one or more components of the electronic device comprise a battery.

27. The system of claim 26, wherein the coil is configured to transfer to the battery heat generated from electrical current driven to the coil.

28. The system of claim 27, wherein the wireless charging circuit is further configured to control delivery of the electrical energy to the battery such that the battery is charged from the wireless charging circuit when a temperature of the battery is above a minimum temperature.

29. The system of claim 26, wherein the coil heating subsystem is configured to drive electrical current from the battery to the coil in order to heat the coil.

30. The system of claim 25, further comprising a temperature reporting subsystem configured to estimate a temperature of the coil.

31. The system of claim 30, wherein the coil heating subsystem is configured to drive electrical current to the coil in order to heat the coil in response to the temperature falling below a threshold temperature.

32. A method comprising:
receiving, by a wireless charging circuit, electrical energy from a source of electrical energy and controlling delivery of the electrical energy to one or more components of an electronic device via a coil which is electrically coupled to the source of electrical energy and wirelessly inductively coupled to the one or more components; and
driving, by a coil heating subsystem, electrical current, other than electrical current provided by the wireless charging circuit, to the coil in order to heat the coil.

33. The method of claim 32, wherein the one or more components of the electronic device comprise a battery.

34. The method of claim 33, further comprising the coil transferring to the battery heat generated from electrical current driven to the coil.

35. The method of claim 34, further comprising controlling delivery of the electrical energy to the battery such that the battery is charged from the wireless charging circuit when a temperature of the battery is above a minimum temperature.

36. The method of claim 33, further comprising driving electrical current from the battery to the coil in order to heat the coil.

37. The method of claim 32, further comprising estimating a temperature of the coil.

38. The method of claim 37, further comprising driving electrical current to the coil in order to heat the coil in response to the temperature falling below a threshold temperature.
